(19) United States
(12) Patent Application Publication
(10) Pub. No.: US 2022/0130974 A1
(43) Pub. Date: Apr. 28, 2022

(54) Contact and Method for Making the Same

(71) Applicant: Shanghai Huali Integrated Circuit Corporation, Shanghai (CN)

(72) Inventors: Jianhua Xu, Shanghai (CN); Zhaoqin Zeng, Shanghai (CN)

(73) Assignee: Shanghai Huali Integrated Circuit Corporation, Shanghai (CN)

(21) Appl. No.: 17/165,448

(22) Filed: Feb. 2, 2021

(30) Foreign Application Priority Data
Oct. 28, 2020 (CN) 202011171786.5

(51) Int. Cl. H01L 29/45; C04B 35/58; C04B 37/02; H01L 29/40; H01L 21/283

(52) U.S. Cl. CPC H01L 29/456; C04B 35/58092; C04B 37/023; H01L 29/401; H01L 21/283; H01L 29/41791; C04B 2237/08; C04B 2237/122; C04B 2237/127; C04B 2237/36; C04B 2237/592; C04B 35/58014

(57) ABSTRACT

The present application discloses a contact, which comprises a contact opening, and a Ti layer, a glue layer and a tungsten layer which completely fill the contact opening; the Ti layer is subjected to annealing treatment; the tungsten layer comprises a tungsten seed layer and a tungsten body layer; the glue layer consists of a TiN layer which is divided into a plurality of TiN sub-layers, all or part of the TiN sub-layers are subjected to the annealing treatment, and the size of grains of the TiN sub-layer subjected to the annealing treatment is limited by the thickness of the corresponding TiN sub-layer. The present application further discloses a method for making a contact. The present application can prevent the annealing treatment of the TiSi layer from producing large lattice grains in the glue layer, thus can make the tungsten seed layer be a continuous structure.

### CROSS-REFERENCE TO RELATED APPLICATIONS

This application claims priority to Chinese Patent Application No. 202011171786.5, filed on Oct. 28, 2020, and entitled “Contact and Method for Making the Same”, the disclosure of which is incorporated herein by reference in entirety.

### TECHNICAL FIELD

The present application relates to the field of semiconductor integrated circuit manufacturing, and in particular to a contact. The present application further relates to a method for making a contact.

### BACKGROUND

In the process flow of the technology node of 14 nm, silicide in a contact adopts a TiSi layer, which is usually formed by adopting a silicide last forming process. In this silicide last forming process, a step of filling a metal layer of the contact includes the following steps:

A Ti layer is formed firstly after selective etching is performed to form a contact opening. On the bottom surface of the contact opening, the Ti layer directly contacts the surface of a silicon substrate, and then a glue layer is formed. The glue layer is usually a TiN layer, and the glue layer will act as a block layer in the subsequent forming process of a tungsten layer, so as to prevent WF6 in the forming process of the tungsten layer from causing an adverse effect on the bottom layer. At the same time, the glue layer has good adhesiveness, which can realize good adhesion between the tungsten layer and an interlayer film. Usually, the Ti layer and TiN are combined together as an adhesion block layer. In order to form silicide needed for self-alignment, in the process of the technology node of 14 nm, the step further includes performing high-temperature annealing after the formation of the Ti layer and the glue layer. The high-temperature annealing makes the Ti layer and silicon on the bottom surface of the contact opening experience silicification reaction to form a TiSi layer.

Then, a tungsten seed layer and a tungsten body layer are formed.

In the existing method, the annealing process introduced in order to form the TiSi layer easily causes the formation of seams in the tungsten layer of the contact, which will influence the quality and yield of products.

### BRIEF SUMMARY

The technical problem to be solved by the present application is to provide a contact, which can adopt a Ti layer combined with a glue layer to form a TiSi layer in a self-aligned manner, can prevent the annealing of the TiSi layer from causing an adverse effect on a tungsten layer in the contact, and can prevent seams from occurring in the tungsten layer. For this purpose, the present application further provides a method for making a contact.

In order to solve the technical problem, the contact provided by the present application includes a contact opening, and a Ti layer, a glue layer and a tungsten layer which completely fill the contact opening;

the contact opening passes through an interlayer film, the interlayer film is formed on a silicon substrate, and the bottom of the contact opening exposes the surface of the silicon substrate;

the Ti layer covers the bottom surface and side surfaces of the contact opening; the Ti layer is subjected to annealing treatment, and the annealing treatment makes the Ti layer and the silicon substrate at the bottom of the contact opening experience silicification reaction to form a TiSi layer;

the tungsten layer includes a tungsten seed layer and a tungsten body layer;

the tungsten seed layer covers the surface of the glue layer;

the glue layer consists of a TiN layer which is divided into a plurality of TiN sub-layers, all or part of the TiN sub-layers are subjected to the annealing treatment, and grains of the TiN sub-layer subjected to the annealing treatment become larger after the annealing treatment;

the size of grains of the TiN sub-layer subjected to the annealing treatment is limited by the thickness of the corresponding TiN sub-layer subjected to the annealing treatment, and the size of grains of the TiN sub-layer subjected to the annealing treatment is limited to make the tungsten seed layer be a continuous structure.

As a further improvement, the TiN layer is divided into two TiN sub-layers, a first TiN sub-layer covers the surface of the Ti layer, a second TiN sub-layer covers the surface of the first TiN sub-layer, the first TiN sub-layer is subjected to the annealing treatment, the second TiN sub-layer is not subjected to the annealing treatment and the second TiN sub-layer is formed after the annealing treatment is completed.

As a further improvement, the TiN sub-layers are all subjected to the annealing treatment, the Ti layer is divided into a plurality of Ti sub-layers, the TiN sub-layers are spaced apart by the corresponding Ti sub-layers, and a first Ti sub-layer is located at the bottommost layer and contacts the silicon substrate at the bottom of the contact opening to form the TiSi layer.

As a further improvement, the TiN layer is divided into two TiN sub-layers, the Ti layer is divided into two Ti sub-layers, a first TiN sub-layer covers the surface of the first Ti sub-layer, a second Ti sub-layer covers the surface of the first TiN sub-layer, and a second TiN sub-layer covers the surface of the second Ti sub-layer.

As a further improvement, the thickness of the Ti layer is 60 Å-120 Å;

the total thickness of the TiN layer is 20 ÅA-40 Å;

the thickness of the first TiN sub-layer is 10 Å-20 Å;

the thickness of the second TiN sub-layer is 10 Å-20 Å.

As a further improvement, the total thickness of the Ti layer is 60 Å-120 Å; the thickness of the first Ti sub-layer is 40 Å-100 Å;

the thickness of the second Ti sub-layer is 10 Å-20 Å;

the total thickness of the TiN layer is 20 Å-40 Å;

the thickness of the first TiN sub-layer is 10 Å-20 Å;

the thickness of the second TiN sub-layer is 10 Å-20 Å.

As a further improvement, a semiconductor device is formed on the silicon substrate and the technology node of the semiconductor device is less than 14 nm.

As a further improvement, the semiconductor device includes a fin field effect transistor (FinFET).

In order to solve the technical problem, the method for making the contact provided by the present application includes the following steps:

step 1: providing a silicon substrate formed with an interlayer film on a surface, and forming a contact opening passing through the interlayer film, the bottom of the contact opening exposing the surface of the silicon substrate;

step 2: forming a superposition structure of a Ti layer and a glue layer,

the Ti layer covering the bottom surface and side surfaces of the contact opening;

after the growth of the Ti layer, step 2 including a sub-step of performing annealing treatment, the annealing treatment making the Ti layer and the silicon substrate at the bottom of the contact opening experience silicification reaction to form a TiSi layer.

the glue layer consisting of a TiN layer, the TiN layer being divided into a plurality of

TiN sub-layers, all or part of the TiN sub-layers being subjected the annealing treatment, and grains of the TiN sub-layer subjected to the annealing treatment becoming larger after the annealing treatment;

the size of grains of the TiN sub-layer subjected to the annealing treatment being limited by the thickness of the corresponding TiN sub-layer subjected to the annealing treatment, and the size of grains of the TiN sub-layer subjected to the annealing treatment being limited to make a subsequently grown tungsten seed layer be a continuous structure;

step 3: forming a tungsten seed layer, the tungsten seed layer covering the surface of the glue layer;

step 4: forming a tungsten body layer, the tungsten seed layer and the tungsten body layer being superposed to form a tungsten layer; the Ti layer, the glue layer and the tungsten layer completely filling the contact opening.

As a further improvement, the TiN layer is divided into two TiN sub-layers, a first

TiN sub-layer covers the surface of the Ti layer, a second TiN sub-layer covers the surface of the first TiN sub-layer, the first TiN sub-layer is subjected to the annealing treatment, the second TiN sub-layer is not subjected to the annealing treatment and the second TiN sub-layer is formed after the annealing treatment is completed.

As a further improvement, the TiN sub-layers are all subjected to the annealing treatment, the Ti layer is divided into a plurality of Ti sub-layers, the TiN sub-layers are spaced apart by the corresponding Ti sub-layers, and a first Ti sub-layer is located at the bottommost layer and contacts the silicon substrate at the bottom of the contact opening to form the TiSi layer.

As a further improvement, the TiN layer is divided into two TiN sub-layers, the Ti layer is divided into two Ti sub-layers, a first TiN sub-layer covers the surface of the first Ti sub-layer, a second Ti sub-layer covers the surface of the first TiN sub-layer, and a second TiN sub-layer covers the surface of the second Ti sub-layer.

As a further improvement, the thickness of the Ti layer is 60 Å-120 Å;

the total thickness of the TiN layer is 20 Å-40 Å;

the thickness of the first TiN sub-layer is 10 Å-20 Å;

the thickness of the second TiN sub-layer is 10 Å-20 Å.

As a further improvement, the total thickness of the Ti layer is 60 Å-120 Å; the thickness of the first Ti sub-layer is 40 Å-100 Å;

the thickness of the second Ti sub-layer is 10 Å-20 Å;

the total thickness of the TiN layer is 20 Å-40 Å;

the thickness of the first TiN sub-layer is 10 Å-20 Å;

the thickness of the second TiN sub-layer is 10 Å-20 Å.

As a further improvement, the TiN sub-layers are all grown by adopting an Atomic

Layer Deposition (ALD) process.

As a further improvement, a semiconductor device is formed on the silicon substrate and the technology node of the semiconductor device is less than 14 nm.

As a further improvement, the semiconductor device includes a FinFET.

In the present application, the TiSi layer in the contact is formed at the bottom of the contact opening through annealing and self-alignment of the Ti layer. In order to prevent the adverse effect caused by the annealing process of the TiSi layer, the structure of the glue layer is improved in the present application. The TiN layer of the glue layer is divided into a plurality of TiN sub-layers under the condition that the thickness required for the functions of the glue layer such as blocking and adhesion functions is satisfied. The size of the grains of the TiN sub-layers subjected to the annealing treatment is limited by setting the thickness of the TiN sub-layers, and the size of the grains of the TiN sub-layers subjected to the annealing treatment is limited to make the tungsten seed layer be a continuous structure.

In the present application, when part of the TiN sub-layers are annealed, the TiN sub-layers not subjected to the annealing treatment will maintain a good lattice grain structure, and the TiN sub-layers not subjected to the annealing treatment will cover the surfaces of the TiN sub-layers subjected to the annealing treatment, finally making the surface in contact with the tungsten seed layer reach an optimal state, be basically not affected by the annealing process and be directly determined by the TiN sub-layers not subjected to the annealing treatment, such that the filling performance of the contact can be greatly improved, and it is conducive to the application of the contact to the technology node of less than 14 nm.

In the present application, when all of the TiN sub-layers are subjected to the annealing treatment, the TiN sub-layers are usually spaced apart by the Ti sub-layers, and the lattice grains of each TiN sub-layer are limited. At the same time, the TiN sub-layers at each top layer are far away from the bottommost Ti sub-layer corresponding to the TiSi layer, such that the size of the lattice grains of the TiN sub-layers at each top layer is reduced due to the influence of the annealing process, finally a very good flat surface structure can be obtained at the TiN sub-layer at the topmost layer, it is conducive to the formation of the continuous structure of the tungsten seed layer, finally the filling performance of the contact can be greatly improved, and it is conducive to the application of the contact to the technology node of less than 14 nm.

### BRIEF DESCRIPTION OF THE DRAWINGS

The present application will be further described below in detail in combination with the embodiments with reference to the drawings.

FIG. 1 is a structural schematic view of a contact according to embodiment 1 of the present application.

FIG. 2 is a structural schematic view of a contact according to embodiment 2 of the present application.

FIG. 3A-FIG. 3E are structural schematic views of a device in each step of a method for making a contact according to embodiment 1 of the present application.

FIG. 4A-FIG. 4F are structural schematic views of a device in each step of a method for making a contact according to embodiment 2 of the present application.

### DETAILED DESCRIPTION OF THE APPLICATION

Embodiment 1 of the present application provides a contact.

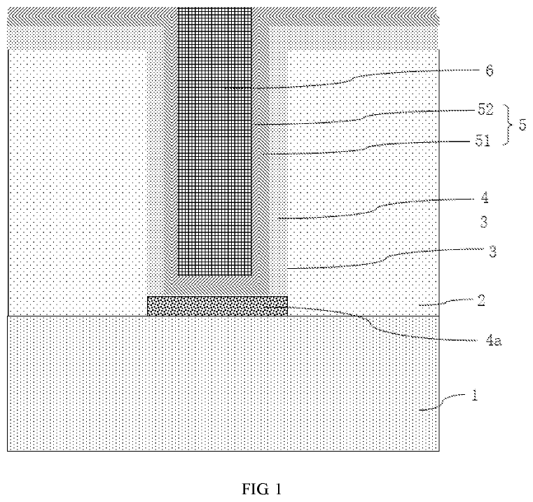

Refer to FIG. 1, which is a structural schematic view of a contact according to embodiment 1 of the present application. The contact according to embodiment 1 of the present application includes a contact opening 3, and a Ti layer 4, a glue layer 5 and a tungsten layer 6 which completely fill the contact opening 3.

The contact opening 3 passes through an interlayer film 2, the interlayer film 2 is formed on a silicon substrate 1, and the bottom of the contact opening 3 exposes the surface of the silicon substrate 1.

The Ti layer 4 covers the bottom surface and side surfaces of the contact opening 3; the Ti layer 4 is subjected to annealing treatment, and the annealing treatment makes the Ti layer 4 and the silicon substrate 1 at the bottom of the contact opening 3 experience silicification reaction to form a TiSi layer 4a.

The tungsten layer 6 includes a tungsten seed layer and a tungsten body layer.

The tungsten seed layer covers the surface of the glue layer 5.

The glue layer 5 consists of a TiN layer which is divided into a plurality of TiN sub-layers, all or part of the TiN sub-layers are subjected to the annealing treatment, and grains of the TiN sub-layer subjected to the annealing treatment become larger after the annealing treatment.

The size of grains of the TiN sub-layer subjected to the annealing treatment is limited by the thickness of the corresponding TiN sub-layer subjected to the annealing treatment, and the size of grains of the TiN sub-layer subjected to the annealing treatment is limited to make the tungsten seed layer be a continuous structure.

In embodiment 1 of the present application, the TiN layer is divided into two TiN sub-layers, a first TiN sub-layer 51 covers the surface of the Ti layer 4, a second TiN sub-layer 52 covers the surface of the first TiN sub-layer 51, the first TiN sub-layer 51 is subjected to the annealing treatment, the second TiN sub-layer 52 is not subjected to the annealing treatment and the second TiN sub-layer 52 is formed after the annealing treatment is completed.

A semiconductor device is formed on the silicon substrate 1, and the technology node of the semiconductor device is less than 14 nm. The semiconductor device includes a FinFET, the FinFET includes fins, and an NMOS and a PMOS are formed on the fins. Since channels may be formed the side surfaces of the fins, the channel width can be increased in case of small size. The semiconductor device includes a source region, a drain region and gates, and the contact is connected with the source region, the drain region and the gates at the bottom. At the technology node of less than 14 nm, usually an embedded epitaxial layer is also formed in the source region or the drain region. The Ti layer 4 at the bottom of the contact opening 3 contacts the surface of the embedded epitaxial layer to form the TiSi layer 4a through annealing. The embedded epitaxial layer of the PMOS is usually an embedded silicon germanium epitaxial layer, and the TiSi layer 4a is formed through silicification reaction between the Ti layer 4 and the embedded silicon germanium epitaxial layer.

The embedded epitaxial layer of the NMOS is usually an embedded silicon phosphorus epitaxial layer, and the TiSi layer 4a is formed through silicification reaction of the Ti layer 4 and the embedded silicon phosphorus epitaxial layer.

In order to more clearly describe embodiment 1 of the present application, in one example of embodiment 1 of the present application, the following parameter settings are adopted:

The thickness of the Ti layer 4 is 60 Å-120 Å.

The total thickness of the TiN layer is 20 Å-40 Å; the thickness setting of 20 Å-40 Å can prevent the overall resistance of the contact from being too high, because the resistivity is high even though the TiN layer is conductive. If the TiN layer is set to be too thick, the resistance of the contact will be increased inevitably. Therefore, the total thickness of the TiN layer should be decreased as much as possible under the condition that the function of the TiN layer used as the glue layer 5 can be guaranteed.

The thickness of the first TiN sub-layer 51 is 10 Å-20 Å. The thickness setting of the first TiN sub-layer 51 can enable the lattice grains of the first TiN sub-layer 51 after annealing treatment to be limited, and the surface non-flatness of the first TiN sub-layer 51 is reduced after the size of the lattice grains is limited.

The thickness of the second TiN sub-layer 52 is 10 Å-20 Å. The second TiN sub-layer 52 is a fresh layer which will not be subjected to the annealing treatment and has a good surface structure. Since the second TiN sub-layer 52 is located on the surface of the first TiN sub-layer 51, the second TiN sub-layer 52 will further cover the non-flat surface structure of the first TiN sub-layer 51. Finally, it is conducive to the formation of the tungsten seed layer.

Embodiment 2 of the present application provides a contact.

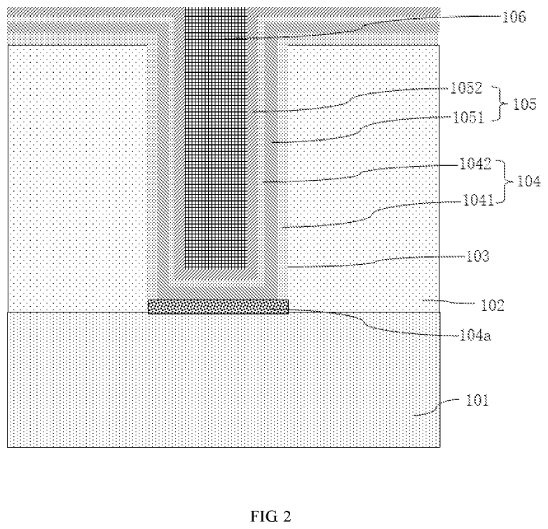

Refer to FIG. 2, which is a structural schematic view of a contact according to embodiment 2 of the present application. The contact according to embodiment 2 of the present application includes a contact opening 103, and a Ti layer 104, a glue layer 105 and a tungsten layer 106 which completely fill the contact opening 103.

The contact opening 103 passes through an interlayer film 102, the interlayer film 102 is formed on a silicon substrate 101, and the bottom of the contact opening 103 exposes the surface of the silicon substrate 101.

The Ti layer 104 covers the bottom surface and side surfaces of the contact opening 103; the Ti layer 104 is subjected to annealing treatment, and the annealing treatment makes the Ti layer 104 and the silicon substrate 101 at the bottom of the contact opening 103 experience silicification reaction to form a TiSi layer 104a.

The tungsten layer 106 includes a tungsten seed layer and a tungsten body layer.

The tungsten seed layer covers the surface of the glue layer 105.

The glue layer 105 consists of a TiN layer which is divided into a plurality of TiN sub-layers, all or part of the TiN sub-layers are subjected to the annealing treatment, and grains of the TiN sub-layer subjected to the annealing treatment become larger after the annealing treatment.

The size of grains of the TiN sub-layer subjected to the annealing treatment is limited by the thickness of the corresponding TiN sub-layer subjected to the annealing treatment, and the size of grains of the TiN sub-layer subjected to the annealing treatment is limited to make the tungsten seed layer be a continuous structure.

In embodiment 2 of the present application, the TiN sub-layers are all subjected to the annealing treatment, the Ti layer 104 is divided into a plurality of Ti sub-layers, the TiN sub-layers are spaced apart by the corresponding Ti sub-layers, and a first Ti sub-layer 1041 is located at the bottommost layer and contacts the silicon substrate 101 at the bottom of the contact opening 103 to form the TiSi layer 104a. As one example, the TiN layer is divided into two TiN sub-layers, the Ti layer is divided into two Ti sub-layers, a first TiN sub-layer 1051 covers the surface of the first Ti sub-layer 1041, a second Ti sub-layer 1042 covers the surface of the first TiN sub-layer 1051, and a second TiN sub-layer 1052 covers the surface of the second Ti sub-layer.

A semiconductor device is formed on the silicon substrate 101, and the technology node of the semiconductor device is less than 14 nm. The semiconductor device includes a FinFET. The semiconductor device includes a source region, a drain region and gates, and the contact is connected with the source region, the drain region and the gates at the bottom. At the technology node of less than 14 nm, usually an embedded epitaxial layer is also formed in the source region or the drain region. The Ti layer 104 at the bottom of the contact opening 103 contacts the surface of the embedded epitaxial layer to form the TiSi layer 104a through annealing. The embedded epitaxial layer of the PMOS is usually an embedded silicon germanium epitaxial layer, and the TiSi layer 104a is formed through silicification reaction between the Ti layer 104 and the embedded silicon germanium epitaxial layer.

The embedded epitaxial layer of the NMOS is usually an embedded silicon phosphorus epitaxial layer, and the TiSi layer 104a is formed through silicification reaction of the Ti layer 104 and the embedded silicon phosphorus epitaxial layer.

In order to more clearly describe embodiment 2 of the present application, in one example of embodiment 2 of the present application, the following parameter settings are adopted:

The total thickness of the Ti layer 104 is 60 Å-120 Å; the thickness of the first Ti sub-layer 1041 is 40 Å-100 Å. The thickness setting of the first Ti sub-layer can ensure that the TiSi layer 104a with sufficient thickness is formed, which is conducive to reducing the contact resistance.

The thickness of the second Ti sub-layer 1042 is 10 Å-20 Å; the thickness setting of the second Ti sub-layer 1042 can ensure that the first TiN sub-layer 1051 and the second TiN sub-layer 1052 are spaced apart and limited well, such that the size of the lattice grains of the first TiN sub-layer 1051 and the second TiN sub-layer 1052 will not increase due to mutual influence.

The total thickness of the TiN layer is 20 Å-40 Å; the thickness setting of 20 Å-40 Å can prevent the overall resistance of the contact from being too high, because the resistivity is high even though the TiN layer is conductive. If the TiN layer is set to be too thick, the resistance of the contact will be increased inevitably. Therefore, the total thickness of the TiN layer should be decreased as much as possible under the condition that the function of the TiN layer used as the glue layer 105 can be guaranteed.

The thickness of the first TiN sub-layer 1051 is 10 Å-20 Å. The thickness setting of the first TiN sub-layer 1051 can enable the lattice grains of the first TiN sub-layer 1051 after annealing treatment to be limited, and the surface non-flatness of the first TiN sub-layer 1051 is reduced after the size of the lattice grains is limited.

The thickness of the second TiN sub-layer 1052 is 10 Å-20 Å. The thickness setting of the second TiN sub-layer 1052 can enable the lattice grains of the second TiN sub-layer 1052 after annealing treatment to be limited. At the same time, the second TiN sub-layer 1052 is farther away from the first Ti sub-layer, so the size of the lattice grains of the second TiN sub-layer 1052 will be further reduced due to the influence of the annealing process, and finally a very good flat surface structure can be obtained at the second TiN sub-layer 1052, which is conducive to the formation of the continuous structure of the tungsten seed layer, finally can greatly improve the filling performance of the contact, and is conducive to the application of the contact to the technology node of less than 14 nm.

Embodiment 1 of the present application further provides a method for making a contact.

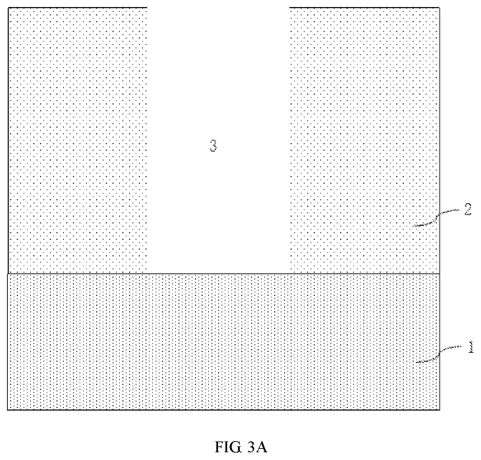

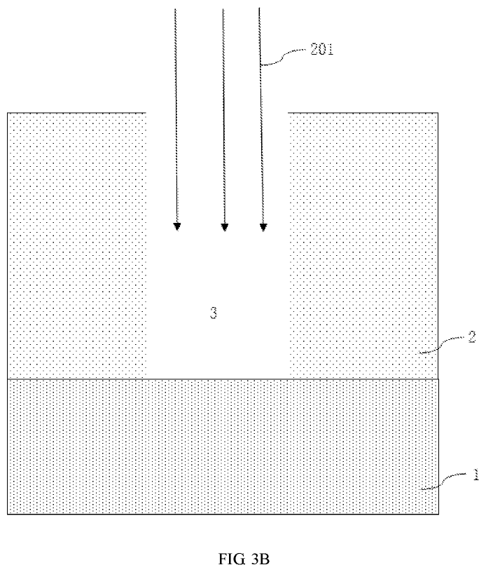

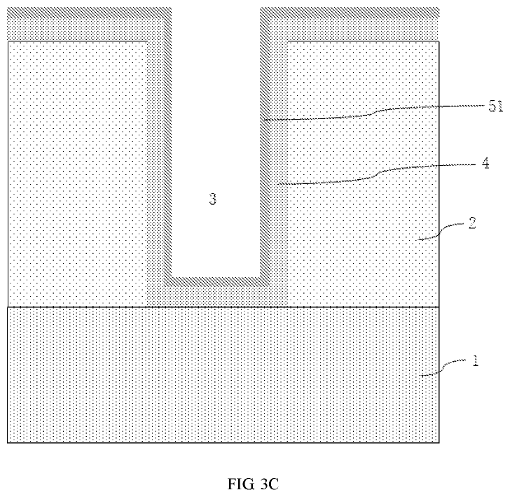

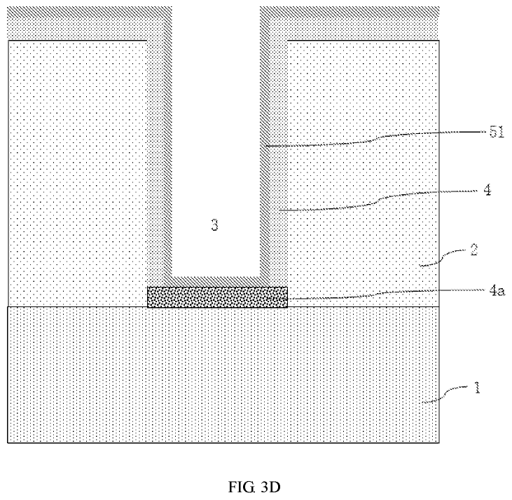

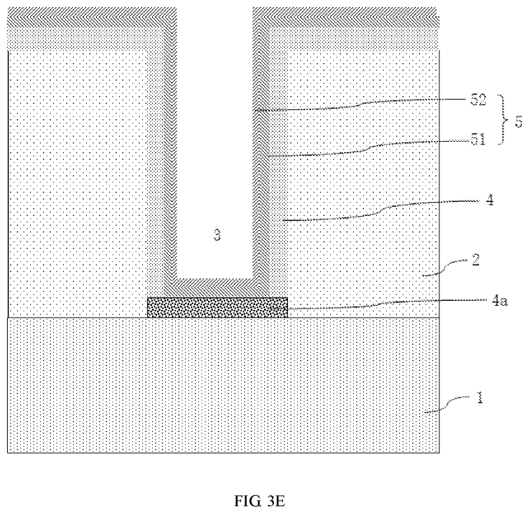

Refer to FIG. 3A-FIG. 3E, which are structural schematic views of a device in each step of the method for making the contact according to embodiment 1 of the present application. The method for making the contact according to embodiment 1 of the present application is used to make the contact illustrated in FIG. 1 according to embodiment 1 of the present application. The method for making the contact according to embodiment 1 of the present application includes the following steps:

In step 1, referring to FIG. 3A, a silicon substrate 1 formed with an interlayer film 2 on a surface is provided, a contact opening 3 passing through the interlayer film 2 is formed, and the bottom of the contact opening 3 exposes the surface of the silicon substrate 1.

A semiconductor device is formed on the silicon substrate 1, and the technology node of the semiconductor device is less than 14 nm. The semiconductor device includes a FinFET. The semiconductor device includes a source region, a drain region and gates, and the contact is connected with the source region, the drain region and the gates at the bottom. At the technology node of less than 14 nm, usually an embedded epitaxial layer is also formed in the source region or the drain region. In this way, the bottom of the contact opening 3 at the top of the source region and the drain region exposes the surface of the embedded epitaxial layer formed on the surface of the silicon substrate 1.

The embedded epitaxial layer of the PMOS is usually an embedded silicon germanium epitaxial layer, and the embedded epitaxial layer of the NMOS is usually an embedded silicon phosphorus epitaxial layer.

The forming region of the contact opening 3 is defined through a photolithography process, and is realized by etching the interlayer film 2 on the basis of definition through the photolithography process.

After the contact opening 3 is formed and before subsequent step 2 is performed, the method further includes the following steps:

Referring to FIG. 3B, pre-amorphorzation implantation (PAI) is performed. The pre-amorphorzation implantation is as illustrated by arrow lines corresponding to reference sign 201.

Pre-cleaning is performed and the pre-cleaning can remove the natural oxide layer on the bottom surface of the contact opening 3.

In step 2, a superposition structure of a Ti layer 4 and a glue layer 5 is formed.

The Ti layer 4 covers the bottom surface and side surfaces of the contact opening 3.

After the growth of the Ti layer 4, step 2 includes a sub-step of performing annealing treatment, and the annealing treatment makes the Ti layer 4 and the silicon substrate 1 at the bottom of the contact opening 3 experience silicification reaction to form a TiSi layer 4a.

When an embedded epitaxial layer is formed on the surface of the silicon substrate 1 at the bottom of the contact opening 3, the Ti layer 4 and silicon in the corresponding embedded epitaxial layer experience silicification reaction to form the TiSi layer 4a. For example, the embedded epitaxial layer of the PMOS is usually an embedded germanium silicon epitaxial layer, and the TiSi layer 4a is formed through silicification reaction of the Ti layer 4 and the embedded germanium silicon epitaxial layer. The embedded epitaxial layer of the NMOS is usually an embedded silicon phosphorus epitaxial layer, and the TiSi layer 4a is formed through silicification reaction of the Ti layer 4 and the embedded silicon phosphorus epitaxial layer.

The glue layer 5 consists of a TiN layer, the TiN layer is divided into a plurality of TiN sub-layers, part of the TiN sub-layers are subjected the annealing treatment, and grains of the TiN sub-layer subjected to the annealing treatment become larger after the annealing treatment.

The size of grains of the TiN sub-layer subjected to the annealing treatment is limited by the thickness of the corresponding TiN sub-layer subjected to the annealing treatment, and the size of grains of the TiN sub-layer subjected to the annealing treatment is limited to make a subsequently grown tungsten seed layer be a continuous structure.

In the method according to embodiment 1 of the present application, the TiN layer is divided into two TiN sub-layers, a first TiN sub-layer 51 covers the surface of the Ti layer 4, a second TiN sub-layer 52 covers the surface of the first TiN sub-layer 51, the first TiN sub-layer 51 is subjected to the annealing treatment, the second TiN sub-layer 52 is not subjected to the annealing treatment and the second TiN sub-layer 52 is formed after the annealing treatment is completed.

The TiN sub-layers are all grown by adopting an atomic layer deposition process.

For the situation that the TiN layer is divided into two TiN sub-layers, step 2 includes the following sub-steps:

Referring to FIG. 3C, a Ti layer 4 is formed.

Then, the first TiN sub-layer 51 is formed by adopting an ALD process.

Referring to FIG. 3D, then annealing is performed, and the annealing makes the Ti layer 4 at the bottom of the contact opening 3 and silicon on the surface of the silicon substrate 1 experience silicification reaction to form the TiSi layer 4a.

Referring to FIG. 3E, the second TiN sub-layer 52 is formed by adopting an ALD process.

In order to more clearly describe the method according to embodiment 1 of the present application, in one example of embodiment 1 of the present application, the following parameter settings are adopted:

The thickness of the Ti layer 4 is 60 Å-120 Å.

The total thickness of the TiN layer is 20 Å-40 Å; the thickness setting of 20 Å-40 Å can prevent the overall resistance of the contact from being too high, because the resistivity is high even though the TiN layer is conductive. If the TiN layer is set to be too thick, the resistance of the contact will be increased inevitably. Therefore, the total thickness of the TiN layer should be decreased as much as possible under the condition that the function of the TiN layer used as the glue layer 5 can be guaranteed.

The thickness of the first TiN sub-layer 51 is 10 Å-20 Å. The thickness setting of the first TiN sub-layer 51 can enable the lattice grains of the first TiN sub-layer 51 after annealing treatment to be limited, and the surface non-flatness of the first TiN sub-layer 51 is reduced after the size of the lattice grains is limited.

The thickness of the second TiN sub-layer 52 is 10 Å-20 Å. The second TiN sub-layer 52 is a fresh layer which will not be subjected to the annealing treatment and has a good surface structure. Since the second TiN sub-layer 52 is located on the surface of the first TiN sub-layer 51, the second TiN sub-layer 52 will further cover the non-flat surface structure of the first TiN sub-layer 51. Finally, it is conducive to the formation of the tungsten seed layer.

In step 3, referring to FIG. 1, a tungsten seed layer is formed and the tungsten seed layer covers the surface of the glue layer 5. Since the surface flatness of the glue layer 5 is finally determined by the surface flatness of the second TiN sub-layer 52, the surface flatness of the second TiN sub-layer 52 is good and it can cover the surface structure of the first TiN sub-layer 51, a continuous tungsten seed layer can be formed finally. The wording “continuous” refers to the structure, for example, the thickness, of the tungsten seed layer on the side surface and bottom surface of the contact opening 3 is continuous, and the situation that tungsten grains are agglomerated and fractured does not occur.

In step 4, referring to FIG. 1, a tungsten body layer is formed. The tungsten seed layer and the tungsten body layer are superposed to form a tungsten layer 6; the Ti layer 4, the glue layer 5 and the tungsten layer 6 completely fill the contact opening 3.

After the tungsten body layer is formed, the method usually further includes a step of performing a metal chemical-mechanical polishing process.

Embodiment 2 of the present application further provides a method for making a contact.

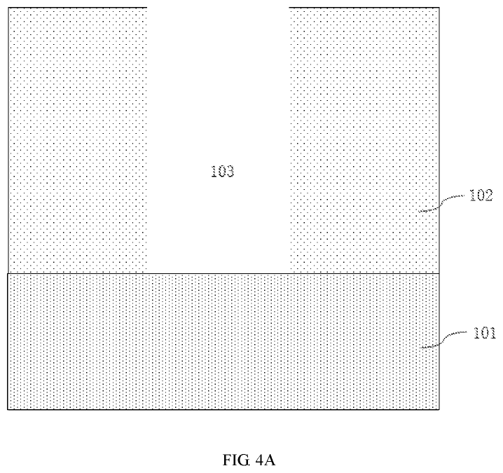

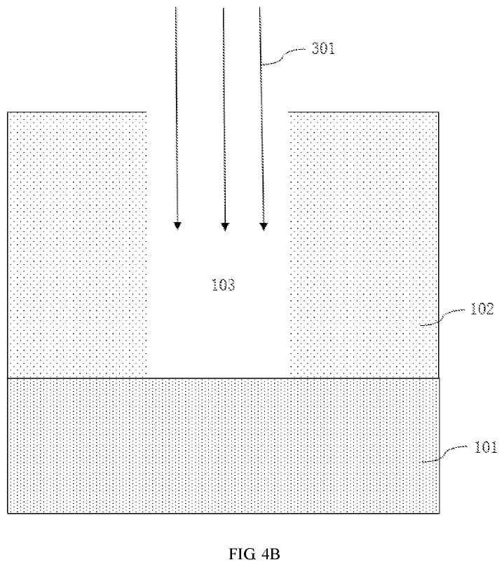

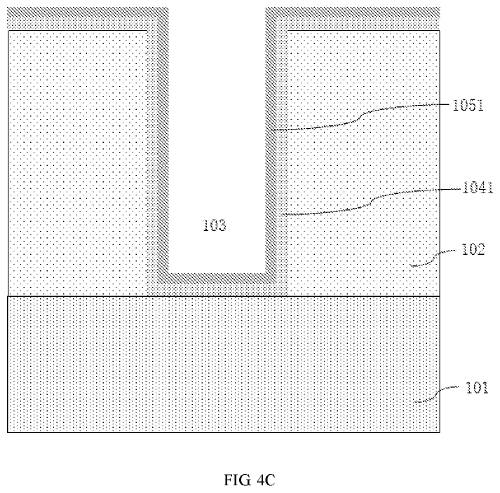

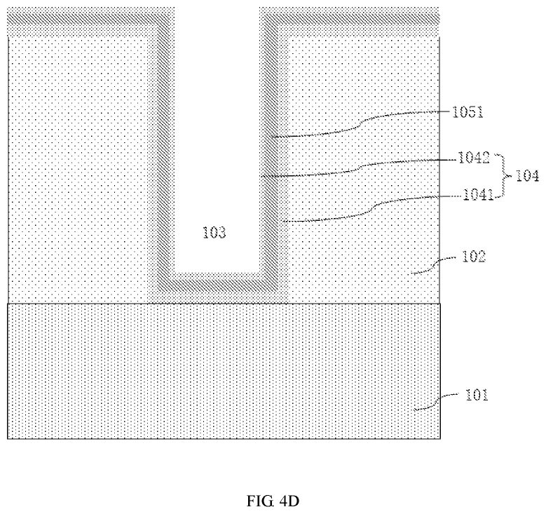

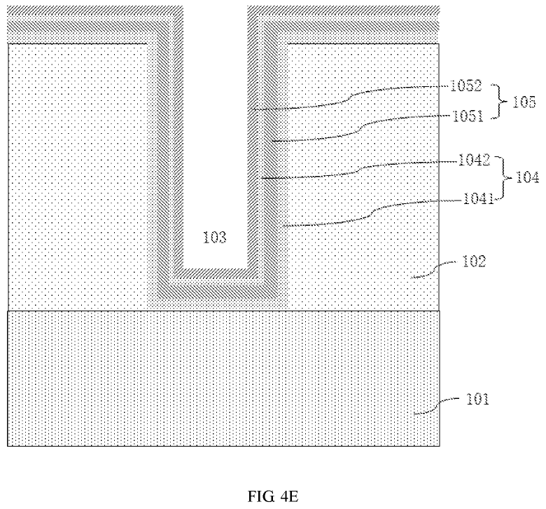

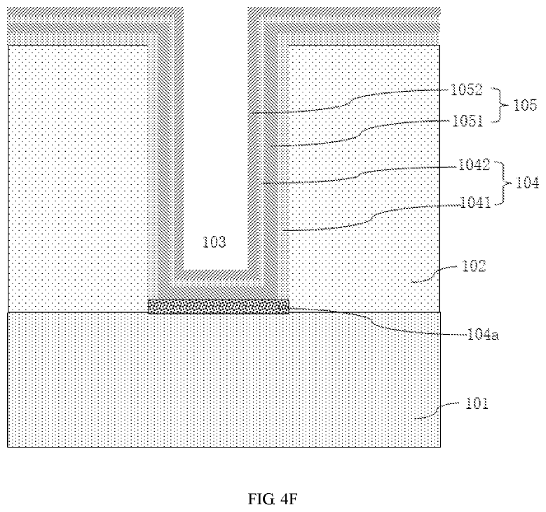

Refer to FIG. 4A-FIG. 4F, which are structural schematic views of a device in each step of the method for making the contact according to embodiment 2 of the present application. The method for making the contact according to embodiment 2 of the present application is used to make the contact illustrated in FIG. 2 according to embodiment 2 of the present application. The method for making the contact according to embodiment 2 of the present application includes the following steps:

In step 1, referring to FIG. 4A, a silicon substrate 101 formed with an interlayer film 102 on a surface is provided, a contact opening 103 passing through the interlayer film 102 is formed, and the bottom of the contact opening 103 exposes the surface of the silicon substrate 101.

A semiconductor device is formed on the silicon substrate 101, and the technology node of the semiconductor device is less than 14 nm. The semiconductor device includes a FinFET. The semiconductor device includes a source region, a drain region and gates, and the contact is connected with the source region, the drain region and the gates at the bottom. At the technology node of less than 14 nm, usually an embedded epitaxial layer is also formed in the source region or the drain region. In this way, the bottom of the contact opening 103 at the top of the source region and the drain region exposes the surface of the embedded epitaxial layer formed on the surface of the silicon substrate 101.

The embedded epitaxial layer of the PMOS is usually an embedded silicon germanium epitaxial layer, and the embedded epitaxial layer of the NMOS is usually an embedded silicon phosphorus epitaxial layer.

The forming region of the contact opening 103 is defined through a photolithography process, and is realized by etching the interlayer film 102 on the basis of definition through the photolithography process.

After the contact opening 103 is formed and before subsequent step 2 is performed, the method further includes the following steps:

Referring to FIG. 4B, pre-amorphorzation implantation (PAI) is performed. The pre-amorphorzation implantation is as illustrated by arrow lines corresponding to reference sign 301.

Pre-cleaning is performed and the pre-cleaning can remove the natural oxide layer on the bottom surface of the contact opening 103.

In step 2, a superposition structure of a Ti layer 104 and a glue layer 105 is formed.

The Ti layer 104 covers the bottom surface and side surfaces of the contact opening 103.

After the growth of the Ti layer 104, step 2 includes a sub-step of performing annealing treatment, and the annealing treatment makes the Ti layer 104 and the silicon substrate 101 at the bottom of the contact opening 103 experience silicification reaction to form a TiSi layer 104a.

When an embedded epitaxial layer is formed on the surface of the silicon substrate 101 at the bottom of the contact opening 103, the Ti layer 104 and silicon in the corresponding embedded epitaxial layer experience silicification reaction to form the TiSi layer 104a. For example, the embedded epitaxial layer of the PMOS is usually an embedded germanium silicon epitaxial layer, and the TiSi layer 104a is formed through silicification reaction of the Ti layer 104 and the embedded germanium silicon epitaxial layer. The embedded epitaxial layer of the NMOS is usually an embedded silicon phosphorus epitaxial layer, and the TiSi layer 104a is formed through silicification reaction of the Ti layer 104 and the embedded silicon phosphorus epitaxial layer.

The glue layer 105 consists of a TiN layer, the TiN layer is divided into a plurality of TiN sub-layers, all the TiN sub-layers are subjected the annealing treatment, and grains of the TiN sub-layer subjected to the annealing treatment become larger after the annealing treatment. The size of grains of the TiN sub-layer subjected to the annealing treatment is limited by the thickness of the corresponding TiN sub-layer subjected to the annealing treatment, and the size of grains of the TiN sub-layer subjected to the annealing treatment is limited to make a subsequently grown tungsten seed layer be a continuous structure.

In the method according to embodiment 2 of the present application, the Ti layer 140 is divided into a plurality of Ti sub-layers, the TiN sub-layers are spaced apart by the corresponding Ti sub-layers, and a first Ti sub-layer 1041 is located at the bottommost layer and contacts the silicon substrate 101 at the bottom of the contact opening 103 to form the TiSi layer 104a.

The TiN layer is divided into two TiN sub-layers, the Ti layer 104 is divided into two Ti sub-layers, a first TiN sub-layer 1051 covers the surface of the first Ti sub-layer 1041, a second Ti sub-layer 1042 covers the surface of the first TiN sub-layer 1051, and a second TiN sub-layer 1052 covers the surface of the second Ti sub-layer 1042.

The TiN sub-layers are all grown by adopting an atomic layer deposition process.

For the situation that the TiN layer is divided into two TiN sub-layers, step 2 includes the following sub-steps:

Referring to FIG. 4C, the first Ti sub-layer 1041 is formed.

Then, the first TiN sub-layer 1051 is formed by adopting an ALD process.

Referring to FIG. 4D, the second Ti sub-layer 1042 is formed.

Referring to FIG. 4E, the second TiN sub-layer 1052 is formed by adopting an ALD process.

Referring to FIG. 4F, then annealing is performed, and the annealing makes the first TiN sub-layer 1051 at the bottom of the contact opening 103 and silicon on the surface of the silicon substrate 1 experience silicification reaction to form the TiSi layer 104a.

In order to more clearly describe the method according to embodiment 2 of the present application, in one example of embodiment 2 of the present application, the following parameter settings are adopted:

The total thickness of the Ti layer 104 is 60 Å-120 Å; the thickness of the first Ti sub-layer 1041 is 40 Å-100 Å. The thickness setting of the first Ti sub-layer 1041 can ensure that the TiSi layer 104a with sufficient thickness is formed, which is conducive to reducing the contact resistance.

The thickness of the second Ti sub-layer 1042 is 10 Å-20 Å; the thickness setting of the second Ti sub-layer 1042 can ensure that the first TiN sub-layer 1051 and the second TiN sub-layer 1052 are spaced apart and limited well, such that the size of the lattice grains of the first TiN sub-layer 1051 and the second TiN sub-layer 1052 will not increase due to mutual influence.

The total thickness of the TiN layer is 20 Å-40 Å; the thickness setting of 20 Å-40 Å can prevent the overall resistance of the contact from being too high, because the resistivity is high even though the TiN layer is conductive. If the TiN layer is set to be too thick, the resistance of the contact will be increased inevitably. Therefore, the total thickness of the TiN layer should be decreased as much as possible under the condition that the function of the TiN layer used as the glue layer 105 can be guaranteed.

The thickness of the first TiN sub-layer 1051 is 10 Å-20 Å. The thickness setting of the first TiN sub-layer 1051 can enable the lattice grains of the first TiN sub-layer 1051 after annealing treatment to be limited, and the surface non-flatness of the first TiN sub-layer 1051 is reduced after the size of the lattice grains is limited.

The thickness of the second TiN sub-layer 1052 is 10 Å-20 Å. The thickness setting of the second TiN sub-layer 1052 can enable the lattice grains of the second TiN sub-layer 1052 after annealing treatment to be limited. At the same time, the second TiN sub-layer 1052 is farther away from the first Ti sub-layer, so the size of the lattice grains of the second TiN sub-layer 1052 will be further reduced due to the influence of the annealing process, and finally a very good flat surface structure can be obtained at the second TiN sub-layer 1052, which is conducive to the formation of the continuous structure of the tungsten seed layer, finally can greatly improve the filling performance of the contact, and is conducive to the application of the contact to the technology node of less than 14 nm.

In step 3, referring to FIG. 2, a tungsten seed layer is formed and the tungsten seed layer covers the surface of the glue layer 105. Since the surface flatness of the glue layer 105 is finally determined by the surface flatness of the second TiN sub-layer 1052, a continuous tungsten seed layer can be formed finally.

In step 4, referring to FIG. 2, a tungsten body layer is formed. The tungsten seed layer and the tungsten body layer are superposed to form a tungsten layer 106; the Ti layer 104, the glue layer 105 and the tungsten layer 106 completely fill the contact opening 103.

After the tungsten body layer is formed, the method usually further includes a step of performing a metal chemical-mechanical polishing process.

The present application has been described above in detail through the specific embodiments, which, however, do not constitute limitations to the present application. Without departing from the principle of the present application, those skilled in the art may make many modifications and improvements, which should also be regarded as included in the scope of protection of the present application.

What is claimed is:

1. A contact, wherein the contact comprises a contact opening, and a Ti layer, a glue layer and a tungsten layer which completely fill the contact opening;
the contact opening passes through an interlayer film, the interlayer film is formed on a silicon substrate, and the bottom of the contact opening exposes the surface of the silicon substrate;
the Ti layer covers the bottom surface and side surfaces of the contact opening; the Ti layer is subjected to annealing treatment, and the annealing treatment makes the Ti layer and the silicon substrate at the bottom of the contact opening experience a silicification reaction to form a TiSi layer;
the tungsten layer comprises a tungsten seed layer and a tungsten body layer;
the tungsten seed layer covers the surface of the glue layer;
the glue layer consists of a TiN layer which is divided into a plurality of TiN sub-layers, all or part of the TiN sub-layers are subjected to the annealing treatment, and grains of the TiN sub-layer subjected to the annealing treatment become larger after the annealing treatment;
the size of grains of the TiN sub-layer subjected to the annealing treatment is limited by the thickness of the corresponding TiN sub-layer subjected to the annealing treatment, and the size of grains of the TiN sub-layer subjected to the annealing treatment is limited to make the tungsten seed layer be a continuous structure.

2. The contact according to claim 1, wherein the TiN layer is divided into two TiN sub-layers, a first TiN sub-layer covers the surface of the Ti layer, a second TiN sub-layer covers the surface of the first TiN sub-layer, the first TiN sub-layer is subjected to the annealing treatment, the second TiN sub-layer is not subjected to the annealing treatment and the second TiN sub-layer is formed after the annealing treatment is completed.

3. The contact according to claim 1, wherein the TiN sub-layers are all subjected to the annealing treatment, the Ti layer is divided into a plurality of Ti sub-layers, the TiN sub-layers are spaced apart by the corresponding Ti sub-layers, and a first Ti sub-layer is located at the bottommost layer and contacts the silicon substrate at the bottom of the contact opening to form the TiSi layer.

4. The contact according to claim 3, wherein the TiN layer is divided into two TiN sub-layers, the Ti layer is divided into two Ti sub-layers, a first TiN sub-layer covers the surface of the first Ti sub-layer, a second Ti sub-layer covers the surface of the first TiN sub-layer, and a second TiN sub-layer covers the surface of the second Ti sub-layer.

5. The contact according to claim 2, wherein the thickness of the Ti layer is 60 Å-120 Å,
the total thickness of the TiN layer is 20 Å-40 Å,
the thickness of the first TiN sub-layer is 10 Å-20 Å, and
the thickness of the second TiN sub-layer is 10 Å-20 Å.

6. The contact according to claim 4, wherein the total thickness of the Ti layer is 60 Å-120 Å, the thickness of the first Ti sub-layer is 40 Å-100 Å,
the thickness of the second Ti sub-layer is 10 ÅA-20 Å,
the total thickness of the TiN layer is 20 |-40 Å,
the thickness of the first TiN sub-layer is 10 Å-20 Å, and
the thickness of the second TiN sub-layer is 10 Å-20 Å.

7. The contact according to claim 1, wherein a semiconductor device is formed on the silicon substrate and the technology node of the semiconductor device is less than 14 nm.

8. The contact according to claim 7, wherein the semiconductor device comprises a FinFET.

9. A method for making a contact, wherein the method for making the contact comprises the following steps:
step 1: providing a silicon substrate formed with an interlayer film on a surface, and forming a contact opening passing through the interlayer film, the bottom of the contact opening exposing the surface of the silicon substrate;
step 2: forming a superposition structure of a Ti layer and a glue layer,
the Ti layer covering the bottom surface and side surfaces of the contact opening;
after the growth of the Ti layer, step 2 comprising a sub-step of performing annealing treatment, the annealing treatment making the Ti layer and the silicon substrate at the bottom of the contact opening experience a silicification reaction to form a TiSi layer.
the glue layer consisting of a TiN layer, the TiN layer being divided into a plurality of TiN sub-layers, all or part of the TiN sub-layers being subjected the annealing treatment, and grains of the TiN sub-layer subjected to the annealing treatment becoming larger after the annealing treatment;
the size of grains of the TiN sub-layer subjected to the annealing treatment being limited by the thickness of the corresponding TiN sub-layer subjected to the annealing treatment, and the size of grains of the TiN sub-layer subjected to the annealing treatment being limited to make a subsequently grown tungsten seed layer be a continuous structure;
step 3: forming a tungsten seed layer, the tungsten seed layer covering the surface of the glue layer; and
step 4: forming a tungsten body layer, the tungsten seed layer and the tungsten body layer being superposed to form a tungsten layer; the Ti layer, the glue layer and the tungsten layer completely filling the contact opening.

10. The method for making the contact according to claim 9, wherein the TiN layer is divided into two TiN sub-layers, a first TiN sub-layer covers the surface of the Ti layer, a second TiN sub-layer covers the surface of the first TiN sub-layer, the first TiN sub-layer is subjected to the annealing treatment, the second TiN sub-layer is not subjected to the annealing treatment and the second TiN sub-layer is formed after the annealing treatment is completed.

11. The method for making the contact according to claim 9, wherein the TiN sub-layers are all subjected to the annealing treatment, the Ti layer is divided into a plurality of Ti sub-layers, the TiN sub-layers are spaced apart by the corresponding Ti sub-layers, and a first Ti sub-layer is located at the bottommost layer and contacts the silicon substrate at the bottom of the contact opening to form the TiSi layer.

12. The method for making the contact according to claim 11, wherein the TiN layer is divided into two TiN sub-layers, the Ti layer is divided into two Ti sub-layers, a first TiN sub-layer covers the surface of the first Ti sub-layer, a second Ti sub-layer covers the surface of the first TiN sub-layer, and a second TiN sub-layer covers the surface of the second Ti sub-layer.

13. The method for making the contact according to claim 10, wherein the thickness of the Ti layer is 60 Å-120 Å,
the total thickness of the TiN layer is 20 Å-40 Å,
the thickness of the first TiN sub-layer is 10 Å-20 Å, and
the thickness of the second TiN sub-layer is 10 Å-20 Å.

14. The method for making the contact according to claim 12, wherein the total thickness of the Ti layer is 60 Å-120 Å, the thickness of the first Ti sub-layer is 40 Å-100 Å,
the thickness of the second Ti sub-layer is 10 Å-20 Å,
the total thickness of the TiN layer is 20 Å-40 Å,
the thickness of the first TiN sub-layer is 10 Å-20 Å, and
the thickness of the second TiN sub-layer is 10 Å-20 Å.

15. The method for making the contact according to claim 9, wherein the TiN sub-layers are all grown by adopting an atomic layer deposition process.

16. The method for making the contact according to claim 9, wherein a semiconductor device is formed on the silicon substrate and the technology node of the semiconductor device is less than 14 nm.

17. The method for making the contact according to claim 16, wherein the semiconductor device comprises a FinFET.
